(19) United States
(12) Patent Application Publication
(10) Pub. No.: US 2024/0266342 A1
(43) Pub. Date: Aug. 8, 2024

(54) COLUMN DIVIDED MULTI-HEIGHT ARCHITECTURE

(71) Applicant: QUALCOMM Incorporated, San Diego, CA (US)

(72) Inventors: Renukprasad HIREMATH, Hillsboro, OR (US); Hyeokjin LIM, San Diego, CA (US); Foua VANG, Sacramento, CA (US); Manjanaika CHANDRANAIKA, Bangalore (IN); Seung Hyuk KANG, San Diego, CA (US); Venugopal BOYNAPALLI, San Diego, CA (US)

(21) Appl. No.: 18/165,259

(22) Filed: Feb. 6, 2023

(51) Int. Cl. H01L 27/02; G06F 30/392

(52) U.S. Cl. CPC H01L 27/0207; G06F 30/392

(57) ABSTRACT

A chip includes a first column including first rails extending in a first direction, the first rails having a first pitch. The chip also includes a second column including second rails extending in the first direction, the second rails having a second pitch different from the first pitch. The chip also includes a transition region between the first column and the second column.

### BACKGROUND

### Field

Aspects of the present disclosure relate generally to chip layout, and, more particularly, to layout of cells on a chip.

### Background

A chip (i.e., die) may include many cells (e.g., thousands to millions of cells) laid out on the chip. Each cell includes one or more transistors that are arranged to provide a logic gate, a latch, a flip-flop, a buffer, and/or another circuit (e.g., a circuit configured to perform a basic function). The layout of each cell may be specified by a standard cell library that defines the layouts for various types of cells that can be placed on the chip.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes a first column including first rails extending in a first direction, the first rails having a first pitch. The chip also includes a second column including second rails extending in the first direction, the second rails having a second pitch different from the first pitch. The chip also includes a transition region between the first column and the second column, wherein an edge of the first column abuts a first edge of the transition region, an edge of the second column abuts a second edge of the transition region, the second edge opposing the first edge, and the first rails are cut at the first edge and the second rails are cut at the second edge.

A second aspect relates to a chip. The chip includes a first column including first cells arranged in first rows, wherein each of the first rows includes respective one or more of the first cells, and each of the first rows extends in a first direction. The chip also includes a second column comprising second cells arranged in second rows, wherein each of the second rows includes respective one or more of the second cells, and each of the second rows extends in the first direction. Each of the first cells is shorter than each of the second cells in a second direction, and the second direction is perpendicular to the first direction.

A third aspect relates to method for chip layout. The method includes receiving an indication of first cells and second cells to be placed on a chip, wherein each of the first cells is shorter than each of the second cells in a first direction. The method also includes determining an area of the first cells, determining an area of the second cells, and determining a first width and a second width based on the area of the first cells and the area of the second cells, wherein the first width and the second width are in a second direction, and the second direction is perpendicular to the first direction. The method also includes laying the first cells in first rows in a first column, the first column having a width approximately equal to the first width, and laying the second cells in second rows in a second column, the second column having a width approximately equal to the second width.

### BRIEF DESCRIPTION OF THE DRAWINGS

FIG. 1 shows a side view of an example of a chip including a transistor, metal layers and vias according to certain aspects of the present disclosure.

FIG. 2A shows a top view of an exemplary layout of a cell according to certain aspects of the present disclosure.

FIG. 2B shows an example of vias on structures in the cell according to certain aspects of the present disclosure.

FIG. 2C shows an example of metal routing and rails according to certain aspects of the present disclosure.

FIG. 3 shows an example of cells laid out in a row on a chip according to certain aspects of the present disclosure.

FIG. 4 shows an example of a layout including alternating rows of tall cells and short cells according to certain aspects of the present disclosure.

FIG. 5 shows an example of a layout including alternating rows of tall cells and short cells with a large imbalance between the tall cells and the short cells according to certain aspects of the present disclosure.

FIG. 6 shows an example of a layout including a first column including short cells and a second column including tall cells according to certain aspects of the present disclosure.

FIG. 7 shows another example of a layout including alternating rows of tall cells and short cells with a large imbalance between the tall cells and the short cells according to certain aspects of the present disclosure.

FIG. 8 shows another example of a layout including a first column including short cells and a second column including tall cells according to certain aspects of the present disclosure.

FIG. 9 shows an example of oxide diffusion (OD) regions in a first column and OD regions in a second column according to certain aspects of the present disclosure.

FIG. 10 is a block diagram illustrating a computer system according to certain aspects of the present disclosure.

FIG. 11 is a flowchart illustrating a method for chip layout according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

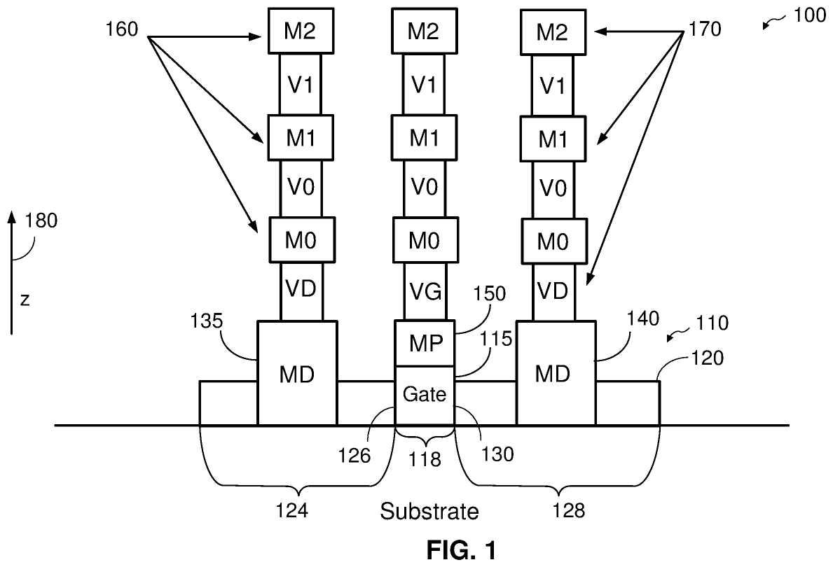

FIG. 1 shows a side view of an example of a chip 100 (i.e., die) according to certain aspects. The chip 100 may include many devices (e.g., transistors) integrated on the chip 100. In this regard, FIG. 1 shows an example of a transistor 110 integrated on the chip 100. Although one transistor 110 is shown in FIG. 1 for simplicity, it is to be appreciated that the chip 100 includes many transistors.

In the example shown in FIG. 1, the transistor 110 includes a gate 115 and at least one fin 120 that extend perpendicularly with respect to the gate 115. The fin 120 may be part of an active region (e.g., oxide diffusion (OD) region), as discussed further below. The gate 115 is formed over a portion of the fin 120 to form a channel 118 of the transistor 110. The transistor 110 may also include a thin gate oxide (not shown) between the gate 115 and the fin 120. The gate 115 may be a poly-silicon gate (also referred to as a poly gate), a metal gate, or another type of gate.

A portion of the fin 120 extending from a first side 126 of the gate 115 forms a first source/drain 124 of the transistor 110, and a portion of the fin 120 extending from a second side 130 of the gate 115 forms a second source/drain 128 of the transistor 110, in which the first side 126 and the second side 130 are opposite sides of the gate 115. As used herein, the term “source/drain” means a source or a drain.

The chip 100 may also include a first source/drain contact 135 formed on the first source/drain 124, and a second source/drain contact 140 formed on the second source/drain 128. The source/drain contacts 135 and 140 may be formed from a source/drain contact layer (e.g., using a lithographic process and an etching process). The source/drain contact layer may also be referred to as a metal diffusion (MD) layer or another term. The chip 100 may also include a gate contact 150 formed on the gate 115.

The gate contact 150 may be formed from a gate contact layer (e.g., using a lithographic process and an etching process). The gate contact layer may also be referred to as a metal poly (MP) layer or another term.

The chip 100 also includes a stack of metal layers 160. The metal layers 160 are patterned (e.g., using a lithographic process and an etching process) to provide metal routing for the transistor 110 and other transistors (not shown in FIG. 1) on the chip 100. For example, the metal routing may be used to interconnect transistors on the chip 100 to form circuits. The metal layers may also be patterned to form supply rails, as discussed further below. The metal layers 160 may also be referred to as metallization layers, or another term. In FIG. 1, the metal layers 160 are stacked in direction 180 (labeled “z”), which is perpendicular to the substrate of the chip 100.

In the example in FIG. 1, the bottom-most metal layer may be designated metal layer M0 (also referred to as metal 0), the metal layer immediately above metal layer M0 may be designated metal layer M1 (also referred to as metal 1), the metal layer immediately above metal layer M1 may be designated metal layer M2 (also referred to as metal 2), and so forth. Although three metal layers are shown in FIG. 1 for ease of illustration, it is to be appreciated that the chip 100 may include additional metal layers (e.g., metal layer M3, metal layer M4, and so forth).

The chip 100 also includes vias 170 that provide electrical coupling between the metal layers 160, and between the metal layer M0 and the contacts 135, 140, and 150. In this example, the vias VD provide electrical coupling between the source/drain contacts 135 and 140 and the metal layer M0, and the via VG provides electrical coupling between the gate contact 150 and the metal layer M0. The vias V0 provide electrical coupling between the metal layer M0 and the metal layer M1, and the vias V1 provide electrical coupling between the metal layer M1 and the metal layer M2.

Although one fin 120 is shown in the example in FIG. 1, it is to be appreciated that the transistor 110 may include multiple fins running parallel to one another. Also, although one gate 115 is shown in the example in FIG. 1, it is to be appreciated that the transistor 110 may include multiple gates running parallel to one another, in which the multiple gates are coupled to one another (e.g., by metal routing formed from metal layer M0). A transistor with multiple gates may be referred to as a multi-gate transistor, a multi-finger transistor, or another term.

The chip 100 (i.e., die) may include many cells (e.g., thousands to millions of cells) laid out on the chip 100. Each cell includes one or more transistors (one or more instances of the transistor 110) that are arranged to provide a logic gate (e.g., an inverter, a NAND gate, a NOR gate, etc.), a latch, a flip-flop, a buffer, and/or another circuit (e.g., a circuit configured to perform a basic function). The layout of each cell may be specified by a standard cell library that defines the layouts for various types of cells that can be placed on the chip 100. The layout of each cell may include the layout of various structures of the one or more transistors in the cell including, for example, the layout of gates (e.g., poly gates), active regions (e.g., oxide diffusion (OD) regions), contacts, etc.

The chip 100 may also include metal routing (also referred to as metal interconnects) for interconnecting cells on the chip 100 to form larger circuits. The metal routing may be formed from one or more of the metal layers 160 shown in FIG. 1 (e.g., using a lithographic process and an etching process). The metal layers 160 may also be used to form supply rails for supplying power to the cells, as discussed further below.

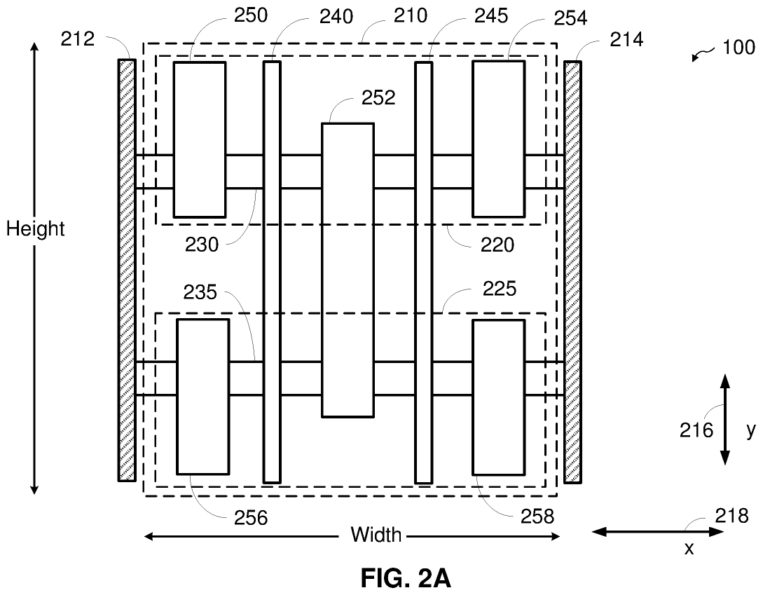

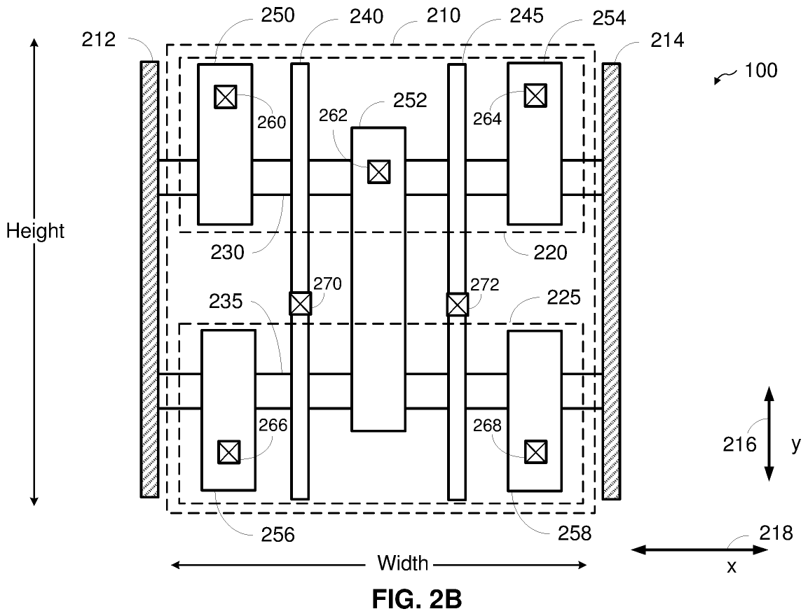

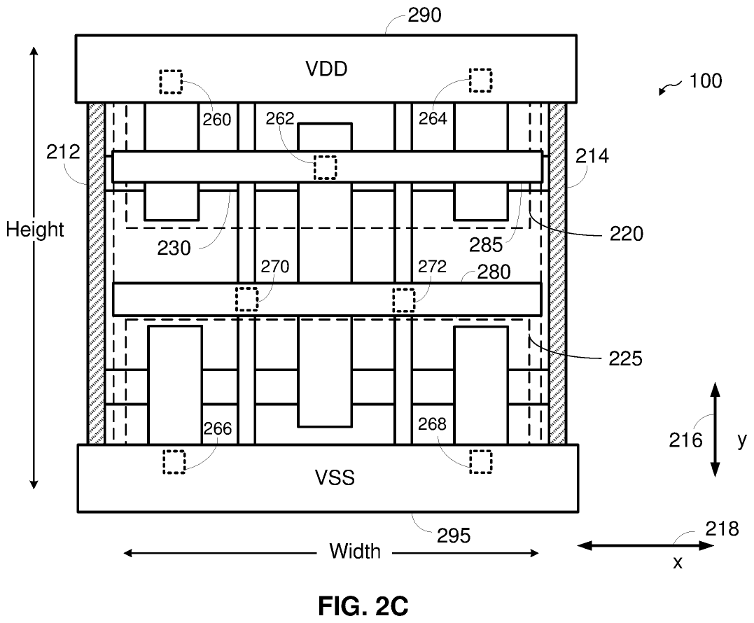

FIG. 2A shows a top view of an example of a cell 210 according to certain aspects. In this example, the cell 210 provides an inverter for performing an inverting function. It is to be understood that multiple instances (i.e., copies) of the exemplary cell 210 may be placed on the chip 100. For example, multiple instances of the exemplary cell 210 may be placed on the chip 100 at various locations on the chip 100 to provide inverters on the chip 100. It is also to be appreciated that the exemplary cell 210 shown in FIG. 2A may be one of several different cells specified in a standard cell library. For example, the standard cell library may include the layouts of other cells that may be placed on the chip 100. The other cells may provide various logic gates, latches, flip-flops, buffers, etc.

In the example in FIG. 2A, the chip 100 includes a first dummy gate 212 and a second dummy gate 214. The first dummy gate 212 may provide a boundary between the cell 210 and a neighboring cell (not shown) to the left of the cell 210, and the second dummy gate 214 may provide a boundary between the cell 210 and a neighboring cell (not shown) to the right of the cell. The first dummy gate 212 may be implemented with a first poly over diffusion edge (PODE), and the second dummy gate 214 may be implemented with a second PODE. However, it is to be understood that the dummy gates 212 and 214 are not limited to this example. It is to be appreciated that a “dummy gate” is not used as a gate of a transistor. In the example shown in FIG. 2A, each of the dummy gates 212 and 214 is elongated and extends in the lateral direction 216 (labeled “y”). As used herein, a “lateral direction” is a direction that runs parallel with the substrate of the chip 100 (i.e., perpendicular to the direction 180 (i.e., z direction) shown in FIG. 1).

In this example, the cell 210 includes a first transistor 220 and a second transistor 225. The first transistor 220 may be a p-type field effect transistor (PFET) and the second transistor 225 may be an n-type field effect transistor (NFET). However, it is to be appreciated that the present disclosure in not limited to this example. FIG. 2A shows an exemplary layout for the first transistor 220 and the second transistor 225, which is discussed further below.

In the example in FIG. 2A, the cell 210 includes a first active region 230 (e.g., first oxide diffusion (OD) region). The first active region 230 extends in the lateral direction 218 (labeled “x”), in which lateral direction 218 is perpendicular to lateral direction 216. In this example, the first active region 230 may be a p-type active region (e.g., OD region) that is formed using p+ diffusion, p+ implantation, or another process. For an example of a fin field-effect transistor (FinFET) process, the first active region 230 may include one or more fins (e.g., one or more instances of the fin 120) extending in the lateral direction 218 (i.e., x direction).

The cell 210 also includes a second active region 235 (e.g., second OD region). The second active region 235 extends in the lateral direction 218. In this example, the second active region 235 may be an n-type active region (e.g., OD region) that is formed using n+ diffusion, n+ implantation, or another process. For the example of a FinFET process, the second active region 235 may include one or more fins (e.g., one or more instances of the fin 120) extending in the lateral direction 218 (i.e., x direction).

The cell 210 also includes a first gate 240 and a second gate 245. The first gate 240 and the second gate 245 may each be a poly-silicon gate, a metal gate, or another type of gate.

Each of the first gate 240 and the second gate 245 is elongated and extends in the lateral direction 216 (i.e., y direction) over the first active region 230 and the second active region 235, as shown in FIG. 2A. The first gate 240 and the second gate 245 are separated from each other in the lateral direction 218 (i.e., x direction). Portions of the first active region 230 under the first gate 240 and the second gate 245 form the channel of the first transistor 220 (e.g., PFET), and portions of the second active region 235 under the first gate 240 and the second gate 245 form the channel of the second transistor 225 (e.g., NFET).

In the example shown in FIG. 2A, each of the transistors 220 and 225 is a two-gate transistor (i.e., two-finger transistor) including two gates (e.g., the first gate 240 and the second gate 245). However, it is to be appreciated that the present disclosure is not limited to this example.

In the example in FIG. 2A, the first gate 240 and the second gate 245 are shared by the first transistor 220 and the second transistor 225. This is because the gates of the first transistor 220 and the second transistor 225 are coupled together to provide the input of the inverter in the cell 210. However, it is to be appreciated that the present disclosure is not limited to this example.

In the example in FIG. 2A, the cell 210 also includes a first source/drain contact 250, a second source/drain contact 252, a third source/drain contact 254, a fourth source/drain contact 256, and a fifth source/drain contact 258. The source/drain contacts 250. 252, 254, 256, and 258 may be formed from a source/drain contact layer (e.g., using a photolithographic process and an etching process). The source/drain contact layer may also be referred to as a metal diffusion (MD) layer, or another term.

In the example in FIG. 2A, the first source/drain contact 250 is disposed over a portion of the first active region 230 between a first boundary (e.g., left side in FIG. 2A) of the cell 210 and the first gate 240, the second source/drain contact 252 is disposed over a portion of the first active region 230 between the first gate 240 and the second gate 245, and the third source/drain contact 254 is disposed over a portion of the first active region 230 between the second gate 245 and a second boundary (e.g., right side in FIG. 2A) of the cell 210. In this example, the first source/drain contact 250 and the third source/drain contact 254 may each provide a source contact for the first transistor 220, and the second source/drain contact 252 may provide a drain contact for the first transistor 220.

In the example in FIG. 2A, the fourth source/drain contact 256 is disposed over a portion of the second active region 235 between the first boundary of the cell 210 and the first gate 240, the fifth source/drain contact 258 is disposed over a portion of the second active region 235 between the second gate 242 and the second boundary of the cell 210, and the second source/drain contact 252 is disposed over a portion of the second active region 235 between the first gate 240 and the second gate 245. In this example, the fourth source/drain contact 256 and the fifth source/drain contact 258 may each provide a source contact for the second transistor 225, and the second source/drain contact 252 may provide a drain contact for the second transistor 225.

In the example in FIG. 2A, the second source/drain contact 252 is shared by the first transistor 220 and the second transistor 225. This is because the drains of the first transistor 220 and the second transistor 225 are coupled together to provide an output of the inverter in the cell 210 in this example. However, it is to be appreciated that the present disclosure is not limited to this example.

FIG. 2A shows a height and a width of the cell 210, in which the height is in the lateral direction 216 (i.e., y direction) and the width is in the lateral direction 218 (i.e., x direction). As discussed further below, the standard cell library may include layouts for other cells with approximately the same height as the cell 210. This allows the cell 210 and the other cells to be placed in the same row on the chip 100, in which the row extends in the lateral direction 218 (i.e., x direction). The other cells may have the same width or different widths.

It is to be appreciated that the cell 210 is not limited to the exemplary layout shown in FIG. 2A. For example, is some implementations, each of the transistors 220 and 225 may be implemented with a single-gate transistor. In these implementations, one of the gates 240 and 245 may be omitted, one of the first and third source/drain contacts 250 and 254 may be omitted, and one of the fourth and fifth source/drain contacts 256 and 258 may be omitted. It is also to be appreciated that the layout may include one or more additional structures not shown in FIG. 2A (e.g., one or more additional gates, one or more additional source/drain contacts, and/or any combination thereof).

FIG. 2B shows an example of vias used to couple various structures of the cell 210 to the metal layer M0. In this example, the chip 100 includes a gate via 270 disposed on the first gate 240 and a gate via 272 disposed on the second gate 245 in the cell 210. It is to be appreciated that, in some implementations, gate contacts (e.g., instances of gate contact 150 in FIG. 1) may be disposed between the gates 240 and 245 and the respective gate vias 270 and 272. A gate via may also be referred to as a VG via.

The chip 100 may also include a via 260 disposed on the first source/drain contact 250, a via 262 disposed on the second source/drain contact 252, a via 264 disposed on the third source/drain contact 254, a via 266 disposed on the fourth source/drain contact 256, and a via 268 disposed on the fifth source/drain contact 258 in the cell 210. It is to be appreciated that the vias 260, 262, 264, 266, 268, 270, and 272 are not limited to the exemplary shapes shown in FIG. 2B. For example, in some implementations, one or more of the vias 260, 262, 264, 266, 268, 270, and 272 may have a rectangular shape or another shape. It is also to be appreciated that the vias 260, 262, 264, 266, 268, 270, and 272 do not need to all have the same shape. It is also to be appreciated that the locations of the vias 260, 262, 264, 266, 268, 270, and 272 are not limited to the exemplary locations shown in FIG. 2B.

FIG. 2C shows an example of a layout of metal routing and rails over the cell 210 according to certain aspects. The metal routing and rails shown in FIG. 2C may be formed from the metal layer M0 (e.g., using photolithography and etching). For ease of illustration, the reference numbers of some of the structures in the cell 210 are omitted in FIG. 2C.

In this example, the chip 100 includes a first metal routing 280 coupled to the gates of the transistors 220 and 225 through the gate vias 270 and 272. The gate vias 270 and 272 are shown with dotted lines in FIG. 2C to indicate that the gate vias 270 and 272 are below the first metal routing 280. The first metal routing 280 is elongated and extends in the lateral direction 218 (i.e., x direction). The first metal routing 280 may be coupled to one or more other cells (e.g., through one or more higher metal layers) to couple the one or more other cells to the input of the inverter in the cell 210.

The chip 100 also includes a second metal routing 285 coupled to the drains of the transistors 220 and 225 through the via 262. The via 262 is shown with dotted lines in FIG. 2C to indicate that the via 262 is below the second metal routing 285. The second metal routing 285 is elongated and extends in the lateral direction 218 (i.e., x direction).

The second metal routing 285 may be coupled to one or more other cells (e.g., through one or more higher metal layers) to couple the one or more other cells to the output of the inverter in the cell 210.

The chip 100 also includes a supply rail 290 that extends in the lateral direction 218 (i.e., x direction). The supply rail 290 may be formed from the same metal layer (e.g., metal layer M0) as the first metal routing 280 and the second metal routing 285 (e.g., using photolithography and etching). The supply rail 290 is coupled to the source of the first transistor 220 through vias 260 and 264 to provide a supply voltage VDD (e.g., from a power distribution network). The supply rail 290 may also be referred to as a supply line, a power bus, or another term.

The chip 100 also includes a low rail 295 that extends in the lateral direction 218 (i.e., x direction). The low rail 295 may be formed from the same metal layer (e.g., metal layer M0) as the first metal routing 280 and the second metal routing 285 (e.g., using photolithography and etching). The low rail 295 is coupled to the source of the second transistor 225 through vias 266 and 268. For example, the low rail 295 may be at ground potential or another potential lower than the supply voltage VDD. For the example where the low rail 295 is at ground potential, the low rail 295 may also be referred to as a ground rail.

It is to be appreciated that the exemplary layout shown in FIG. 2C may be vertically flipped so that the second transistor 225 and the low rail 295 are above the first transistor 220 and the supply rail 290 in the lateral direction 216 (i.e., y direction).

In the example in FIG. 2A, the metal routing and rails formed from the metal layer M0 extend in the lateral direction 218 (i.e., x direction). Metal routing formed from the metal layer M1 (not shown in FIG. 2C) may extend in the lateral direction 216 (i.e., y direction).

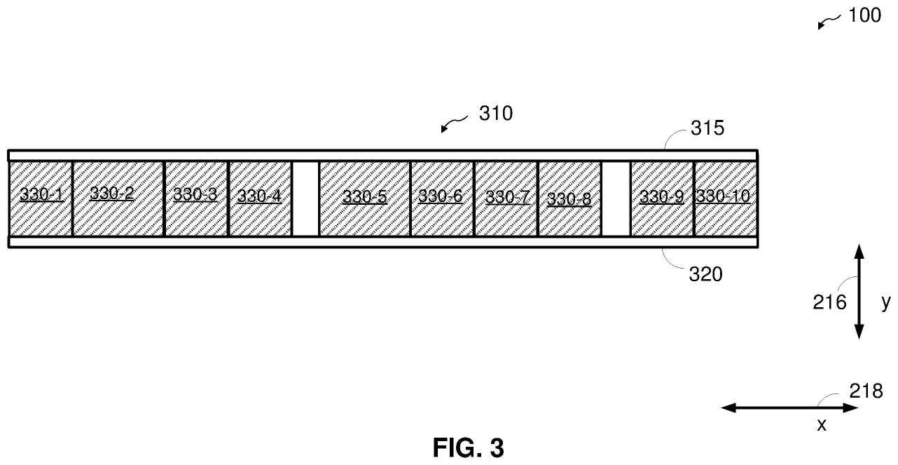

FIG. 3 shows an exemplary layout in which cells 330-1 to 330-10 are laid out in a row 310 on the chip 100. The row 310 extends in the lateral direction 218 (i.e., x direction). In this example, the cells 330-1 to 330-10 have approximately the same height where height is in the lateral direction 216 (i.e., y direction). As shown in FIG. 3, the widths of the cells 330-1 to 330-10 may vary, where the widths are in the lateral direction 218 (i.e., x direction). However, it is to be appreciated that this need not be the case, and that the cells 330-1 to 330-10 may have the same width in other implementations. In FIG. 3, the cells 330-1 to 330-10 are shaded. Although not shown in FIG. 3, it is to be appreciated that adjacent cells may be separated by dummy gates (e.g., PODEs).

The cells 330-1 to 330-10 may include one or more instances of the cell 210. The cells 330-1 to 330-10 may include different cells from a standard cell library. The cells 330-1 to 330-10 may include one or more logic gates, one or more latches, one or more flip-flops, one or more buffers, etc.

The chip 100 also includes a first rail 315 and a second rail 320. In this example, the cells 330-1 to 330-10 are between the first rail 315 and the second rail 320. The first rail 315 and the second rail 320 extend in the lateral direction 218 (i.e., x direction), and may be formed from the metal layer M0 or another metal layer (e.g., using photolithography and etching). The first and second rails 315 and 320 may be used to provide power to the cells 330-1 to 330-10 in the row 310, in which the first rail 315 includes a supply rail (e.g., supply rail 290) and the second rail 320 includes a low rail (e.g., low rail 295), or vice versa. The first and second rails 315 and 320 may be coupled to source/drain contacts (not shown in FIG. 3) and/or other structures in the cells 330-1 to 330-10 through vias (not shown in FIG. 3).

In certain aspects, the cells in the standard cell library may be categorized by height, where height is taken in the lateral direction 216 (i.e., y direction). For example, the standard cell library may include tall cells and short cells, in which the height of the tall cells is taller (i.e., higher) than the height of the short cells.

In some implementations, the tall cells may include larger transistors than the short cells for higher performance (e.g., higher drive strength) while the short cells may include smaller transistors for reduced power consumption. For example, a larger transistor may include a larger number of fins (e.g., a larger active region) than a smaller transistor. In these aspects, tall cells may be used for circuits requiring high performance (e.g., a circuit operating at a high speed, a circuit with tight timing constraints, etc.). Short cells may be used to conserve power for circuits that do not require high performance. However, it is to be appreciated that the present disclosure is not limited to this example.

The standard cell library may include tall cells for providing logic gates, latches, flip-flops, buffers, etc. The standard cell library may also include short cells for providing logic gates, latches, flip-flops, buffers, etc. It is to be appreciated that the standard cell library may include a tall cell and a short cell that perform the same or substantially the same function. For example, a tall cell and a short cell may both include a buffer in which the buffer in the tall cell has a higher drive strength than the buffer in the short cell (e.g., for high-speed applications).

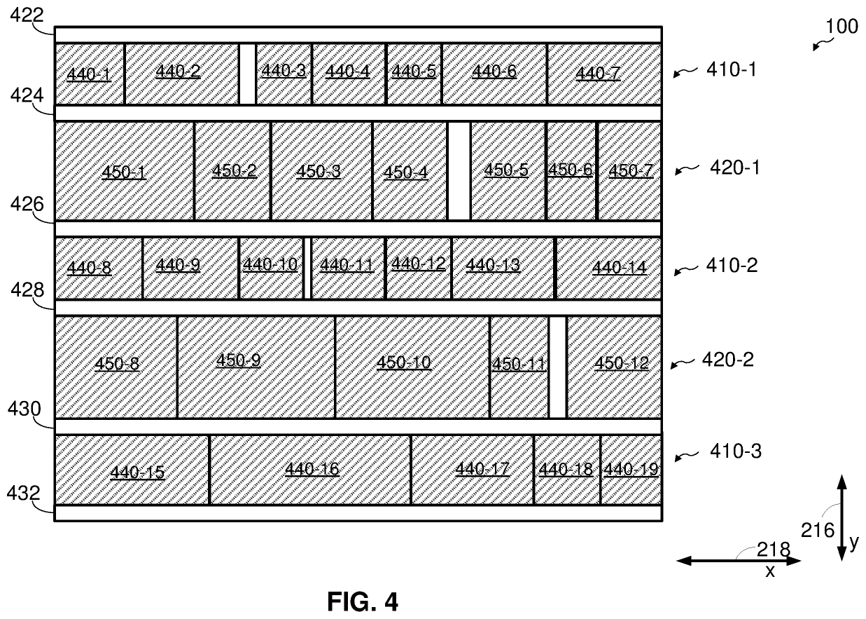

In one approach, tall cells and short cells are laid out on the chip 100 in alternating rows. In this regard, FIG. 4 shows an example of a layout including short rows 410-1, 410-2, and 410-3 and tall rows 420-1 and 420-2, in which the layout alternates between the short rows 410-1, 410-2, and 410-3 and the tall rows 420-1 and 420-2 in the lateral direction 216 (i.e., y direction). Each of the short rows 410-1, 410-2, and 410-3 and each of the tall rows 420-1 and 420-2 extends in the lateral direction 218 (i.e., x direction). The height of each of the short rows 410-1, 410-2, and 410-3 is approximately equal to a first height, and the height of each of the tall rows 420-1 and 420-2 is approximately equal to a second height, where the first height is shorter (i.e., lower) than the second height, and height is taken in the lateral direction 216 (i.e., y direction). For example, the first height may be equal to ⅔ of the second height (i.e., the height of each of the short rows 410-1, 410-2, and 410-3 may be approximately ⅔ the height of each of the tall rows 420-1 and 420-2). However, it is to be appreciated that the present disclosure is not limited to this example. It is also to be appreciated that the layout shown in FIG. 4 may include additional short rows and tall rows that alternate in the lateral direction 216 (i.e., y direction).

The layout also includes rails 422, 424, 426, 428, 430, and 432 between the rows 410-1, 410-2, 410-3, 420-1, and 420-2. A used herein, a “rail” may include a supply rail or a low rail. A rail may also be referred to as a voltage rail. Each of the rails 422, 424, 426, 428, 430, and 432 extends in the lateral direction 218 (i.e., x direction), and may be formed (i.e., patterned) from the metal layer M0 or another metal layer.

In the example shown in FIG. 4, the short row 410-1 is between the rail 422 and the rail 424, where the rail 422 may include a supply rail and the rail 424 may include a low rail, or vice versa. The tall row 420-1 is between the rail 424 and the rail 426, where the rail 424 may include a supply rail and the rail 426 may include a low rail, or vice versa. The short row 410-2 is between the rail 426 and the rail 428, where the rail 426 may include a supply rail and the rail 428 may include a low rail, or vice versa. The tall row 420-2 is between the rail 428 and the rail 430, where the rail 428 may include a supply rail and the rail 430 may include a low rail, or vice versa. The short row 410-3 is between the rail 430 and the rail 432, where the rail 430 may include a supply rail and the rail 432 may include a low rail, or vice versa.

The layout also includes short cells 440-1 to 440-19 where the short cells 440-1 to 440-7 are in the short row 410-1, the short cells 440-8 to 440-14 are in the short row 410-2, and the short cells 440-15 to 440-19 are in the short row 410-3. The short cells 440-1 to 440-19 may include one or more instances (i.e., copies) of the exemplary cell 210 and/or other cells from the standard cell library. The rails 422 and 424 may be used to provide power to the short cells 440-1 to 440-7 in the short row 410-1. For example, the rails 422 and 424 may be coupled to source/drain contacts and/or other structures in the short cells 440-1 to 440-7 through vias (not shown in FIG. 4). Examples of source/drain contacts (e.g., source/drain contacts 250, 252, 254, 256, and 258) are shown in FIGS. 2A, 2B, and 2C. The rails 426 and 428 may be used to provide power to the short cells 440-8 to 440-14 in the short row 410-2. For example, the rails 426 and 428 may be coupled to source/drain contacts and/or other structures in the short cells 440-8 to 440-14 through vias (not shown in FIG. 4). The rails 430 and 432 may be used to provide power to the short cells 440-15 to 440-19 in the short row 410-3. For example, the rails 430 and 432 may be coupled to source/drain contacts and/or other structures in the short cells 440-15 to 440-19 through vias (not shown in FIG. 4).

The layout also includes tall cells 450-1 to 450-12 where the tall cells 450-1 to 450-7 are in the tall row 420-1, and the tall cells 450-8 to 450-12 are in the tall row 420-2. The tall cells 450-1 to 450-12 may include one or more instances (i.e., copies) of the exemplary cell 210 and/or other cells from the standard cell library. The rails 424 and 426 may be used to provide power to the tall cells 450-1 to 450-7 in the tall row 420-1. For example, the rails 424 and 426 may be coupled to source/drain contacts and/or other structures in the tall cells 450-1 to 450-7 through vias (not shown in FIG. 4). Examples of source/drain contacts (e.g., source/drain contacts 250, 252, 254, 256, and 258) are shown in FIGS. 2A, 2B, and 2C. The rails 428 and 430 may be used to provide power to the tall cells 450-8 to 450-12 in the tall row 420-2. For example, the rails 428 and 430 may be coupled to source/drain contacts and/or other structures in the tall cells 450-8 to 450-12 through vias (not shown in FIG. 4).

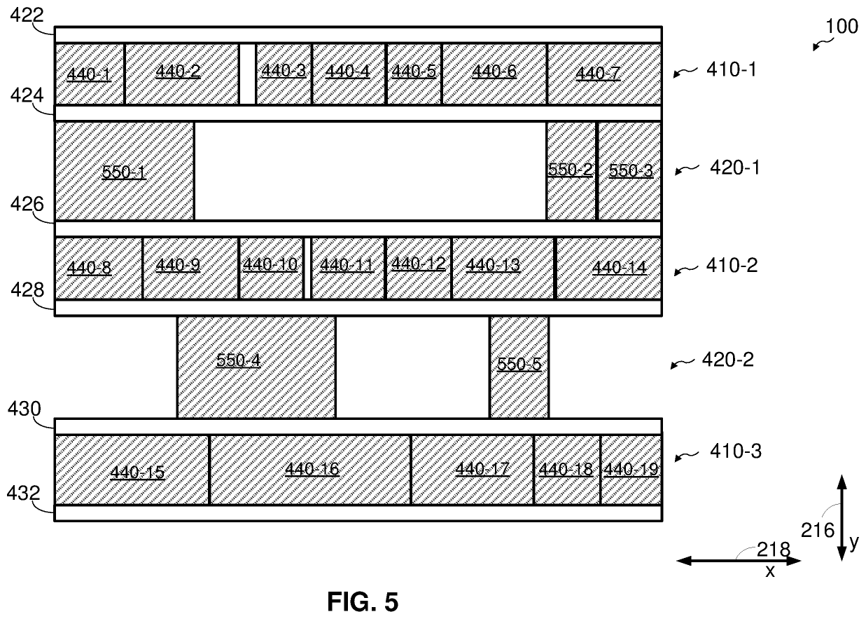

A drawback of the layout approach shown in FIG. 4 is that this layout approach leads to inefficient use of chip area for cases where there is a large imbalance between short cells and tall cells. In this regard, FIG. 5 shows an example in which the short cells take up a disproportionately larger chip area than the tall cells. In this example, the layout includes the short cells 440-1 to 440-19 discussed above with reference to FIG. 4. However, the layout in this example includes a much smaller number of tall cells 550-1 to 550-5 compared with FIG. 4. As shown in FIG. 5, the large imbalance between the short cells 440-1 to 440-19 and the tall cells 550-1 to 550-5 results in large empty spaces in the tall rows 420-1 and 420-2, and therefore an inefficient use of chip area.

To address this, aspects of the present disclosure provide a layout approach in which short cells and tall cells on the chip 100 are divided into columns. In certain aspects, the widths of the columns may be customizable based on the proportion of tall cells and the proportion of short cells on the chip. As discussed further below, the columns provide higher area efficiency compare with the layout approach in FIG. 4 for cases where there is an imbalance between the tall cells and the short cells.

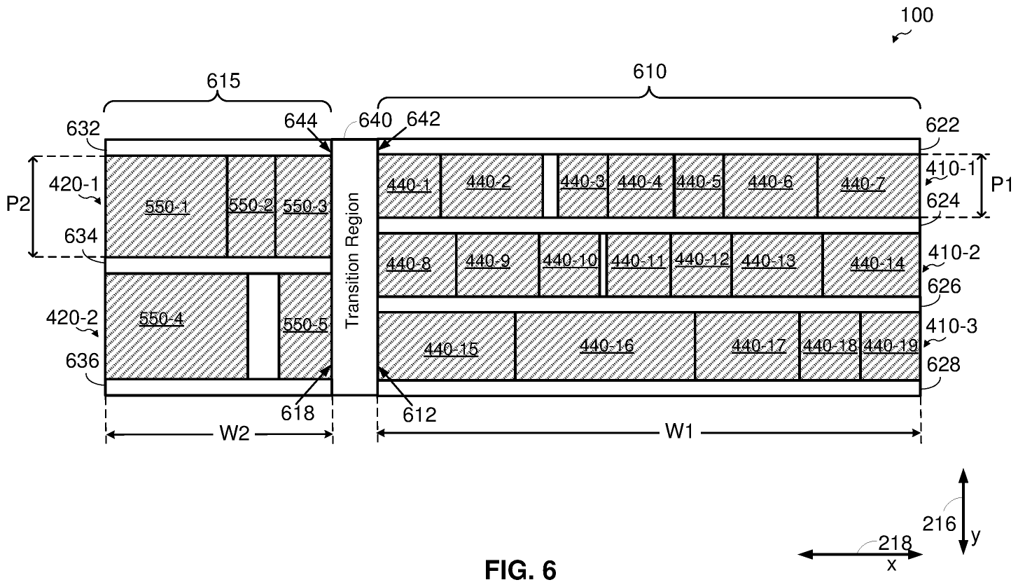

FIG. 6 shows an example of a layout including a first column 610 and a second column 615 according to aspects of the present disclosure. The first column 610 includes rails 622, 624, 626, and 628, and the second column 615 includes rails 632, 634, and 636.

Although the first column 610 is shown to the right of the second column 615 in the example in FIG. 6, it is to be appreciated that the present disclosure is not limited to this example. For example, the first column 610 may be located to the left of the second column 615 in some implementations.

Each of the rails 622, 624, 626, and 628 in the first column 610 is elongated and extends in the lateral direction 218 (i.e., x direction). In other words, the rails 622, 624, 626, and 628 run parallel to one another. Each of the rails 622, 624, 626, and 628 may be formed (i.e., patterned) from the metal layer M0 or another metal layer (e.g., using a lithographic process and an etching process). For example, each of the rails 622, 624, 626, and 628 may include a metal line formed from the metal layer M0 or another metal layer. The rails 622, 624, 626, and 628 in the first column 610 may also be referred to as first rails.

Each of the rails 632, 634, and 636 in the second column 615 is elongated and extends in the lateral direction 218 (i.e., x direction). In other words, the rails 632, 634, and 636 run parallel to one another. Each of the rails 632, 634, and 636 may be formed (i.e., patterned) from the metal layer M0 or another metal layer (e.g., using a lithographic process and an etching process). For example, each of the rails 632, 634, and 636 may include a metal line formed from metal layer M0 or another metal layer. The rails 632, 634, and 636 in the second column 615 may also be referred to as second rails.

As shown in FIG. 6, the rails 622, 624, 626, and 628 in the first column have a first pitch (labeled “P1”). As used herein, “pitch” is the spacing (i.e., distance) between adjacent rails in the lateral direction 216 (i.e., y direction). As discussed further below, the first pitch accommodates the placement of rows of short cells between the rails 622, 624, 626, and 628, in which the short cells receive power via the rails 622, 624, 626, and 628.

The rails 632, 634, and 636 in the second column 615 have a second pitch (labeled P2″), which is different from the first pitch. As discussed further below, the second pitch accommodates the placement of rows of tall cells between the rails 632, 634, and 636, in which the tall cells receive power via the rails 632, 634, and 636. Since the tall cells having a taller height than the short cells, the second pitch (which accommodates tall cells) is greater than the first pitch (which accommodates short cells). In one example, the first pitch is approximately equal to ⅔ of the second pitch. As discussed further below, making the first pitch approximately equal to ⅔ of the second pitch facilitates the placement of three rows of short cells for every two rows of tall cells. However, it is to be appreciated that the first pitch and the second pitch are not limited to this example. As used herein, “approximately equal to” is between 95% to 105% of the stated value.

The layout also includes a transition region 640 between the first column 610 and the second column 615 in the lateral direction 218 (i.e., x direction). As discussed further below, the transition region 640 provides a transition between the rails 622, 624, 626, and 628 in the first column 610 and the rails 632, 634, and 636 in the second column 615. In the example in FIG. 6, the transition region 640 has a first edge 642 and a second edge 644, in which the rails 622, 624, 626, and 628 are cut at the first edge 642 of the transition region 640, and the rails 632, 634, and 636 are cut at the second edge 644 of the transition region 640. The second edge 644 opposes the first edge 642 (i.e., the second edge 644 and the first edge 642 are on opposite sides of the transition region 640). Also, the first edge 642 of the transition region 640 abuts an edge 612 of the first column 610, and the second edge 644 of the transition region 640 abuts an edge 618 of the second column 615.

In the example shown in FIG. 6, the edges 612, 618, 642, and 644 extend in the lateral direction 216 (i.e., y direction).

The first column 610 includes the short cells 440-1 to 440-19 arranged in the short rows 410-1, 410-2, and 410-3. The second column 615 includes the tall cells 550-1 to 550-5 arranged in the tall rows 420-1 and 420-2. As discussed above, each of the short rows 410-1, 410-2, and 410-3 and each of the tall rows 420-1 and 420-2 extends in the lateral direction 218 (i.e., x direction). The transition region 640 provides a transition between short rows 410-1, 410-2, and 410-3 in the first column 610 and the tall rows 420-1 and 420-2 in the second column 615.

In the example in FIG. 6, the height of each of the short rows 410-1, 410-2, and 410-3 may be approximately equal to the first height, and the height of each of the tall rows 420-1 and 420-2 may be approximately equal to the second height, where height is in lateral direction 216 (i.e., y direction). As used herein, “approximately equal to” is between 95% to 105% of the stated height. For example, a height approximately equal to the first height is between 95% to 105% of the first height. In one example, the first height is equal to ⅔ of the second height. Thus, the height of three of the short rows 410-1, 410-2, and 410-3 is approximately equal to the height of two of the tall rows 420-1 and 420-2 in this example. In this example, the first column 610 and the second column 615 may have approximately the same height, in which the first column 610 includes three short rows for every two tall rows in the second column 615. However, it is to be appreciated that the present disclosure is not limited to this example.

In the example shown in FIG. 6, the short row 410-1 is between the rail 622 and the rail 624, where the rail 622 may include a supply rail and the rail 624 may include a low rail, or vice versa. The short row 410-2 is between the rail 624 and the rail 626, where the rail 624 may include a supply rail and the rail 626 may include a low rail, or vice versa. The short row 410-3 is between the rail 626 and the rail 628, where the rail 626 may include a supply rail and the rail 628 may include a low rail, or vice versa. Thus, each of the short rows 410-1, 410-2, and 410-3 is between a respective pair of the rails 622, 624, 626, and 628. Note that two pairs of rails may have one of the rails 622, 624, 626, and 628 in common. For example, the pair of rails 622 and 624 and the pair of rails 624 and 626 have the rail 624 in common.

The tall row 420-1 is between the rail 632 and the rail 634, where the rail 632 may include a supply rail and the rail 634 may include a low rail, or vice versa. The tall row 420-2 is between the rail 634 and the rail 636, where the rail 634 may include a supply rail and the rail 636 may include a low rail, or vice versa. Thus, each of the tall rows 420-1 and 420-2 is between a respective pair of the rails 632, 634, and 636. Note that two pairs of rails may have one of the rails 632, 634, and 636 in common.

In the example in FIG. 6, the rail 632 and the rail 622 are aligned in the lateral direction 216 (i.e., y direction), and the rail 636 and the rail 628 are aligned in the lateral direction 216 (i.e., y direction). The rail 634 is not aligned with either one of the rails 624 and 626 in the lateral direction 216 (i.e., y direction). This is because the rails 632, 634, and 636 have a different pitch than the rails 622, 624, 626, and 628.

Each of the short rows 410-1, 410-2, and 430-3 includes respective one or more of the short cells 440-1 to 440-19. In the example in FIG. 6, the short cells 440-1 to 440-7 are in the short row 410-1, the short cells 440-8 to 440-14 are in the short row 410-2, and the short cells 440-15 to 440-19 are in the short row 410-3. The rails 622 and 624 may be used to provide power to the short cells 440-1 to 440-7 in the short row 410-1. For example, the rails 622 and 624 may be coupled to source/drain contacts and/or other structures in the short cells 440-1 to 440-7 through vias (not shown in FIG. 6). The rails 624 and 626 may be used to provide power to the short cells 440-8 to 440-14 in the short row 410-2. For example, the rails 624 and 626 may be coupled to source/drain contacts and/or other structures in the short cells 440-8 to 440-14 through vias (not shown in FIG. 6). The rails 626 and 628 may be used to provide power to the short cells 440-15 to 440-19 in the short row 410-3. For example, the rails 626 and 628 may be coupled to source/drain contacts and/or other structures in the short cells 440-15 to 440-19 through vias (not shown in FIG. 6).

Each of the tall rows 420-1 and 420-2 includes respective one or more of the tall cells 550-1 to 550-5. In the example in FIG. 6 tall cells 550-1 to 550-3 are in the tall row 420-1, and the tall cells 550-4 and 550-5 are in the tall row 420-2. The rails 632 and 634 may be used to provide power to the tall cells 550-1 to 550-3 in the tall row 420-1. For example, the rails 632 and 634 may be coupled to source/drain contacts and/or other structures in the tall cells 550-1 to 550-3 through vias (not shown in FIG. 6). The rails 634 and 636 may be used to provide power to the tall cells 550-4 and 550-5 in the tall row 420-2. For example, the rails 634 and 636 may be coupled to source/drain contacts and/or other structures in the tall cells 550-4 and 550-5 through vias (not shown in FIG. 6).

In certain aspects, the width of the first column 610 is approximately equal to a first width (labeled “W1”) and the width of the second column 615 is approximately equal to a second width (labeled “W2”), where width is in the lateral direction 218 (i.e., x direction). In certain aspects, the first width and the second width may be customized based on the proportion of tall cells and the proportion of short cells on the chip. For cases where the short cells take up a disproportionately larger chip area than the tall cells, the first width may be made greater (i.e., wider) than the second width, and, for cases where the tall cells take up a disproportionately larger chip area than the short cells, the second width may be made greater (i.e., wider) than the first width. In the example shown in FIG. 6, the first width is wider than the second width since the short cells 440-1 to 440-19 take up a disproportionately larger chip area than the tall cells 550-1 to 550-5 in this example (i.e., the area of the short cells 440-1 to 440-19 is greater than the area of the tall cells 550-1 to 550-5). As a result, the width of the tall rows 420-1 to 420-2 in the second column 615 is smaller than the width of the tall rows 420-1 to 420-2 in FIG. 5. The smaller width of the tall rows 420-1 to 420-2 in the second column 615 significantly reduces the amount of empty space in the tall rows 420-1 to 420-2 compared with the layout in FIG. 5, thereby improving chip area efficiently compared with the layout in FIG. 5.

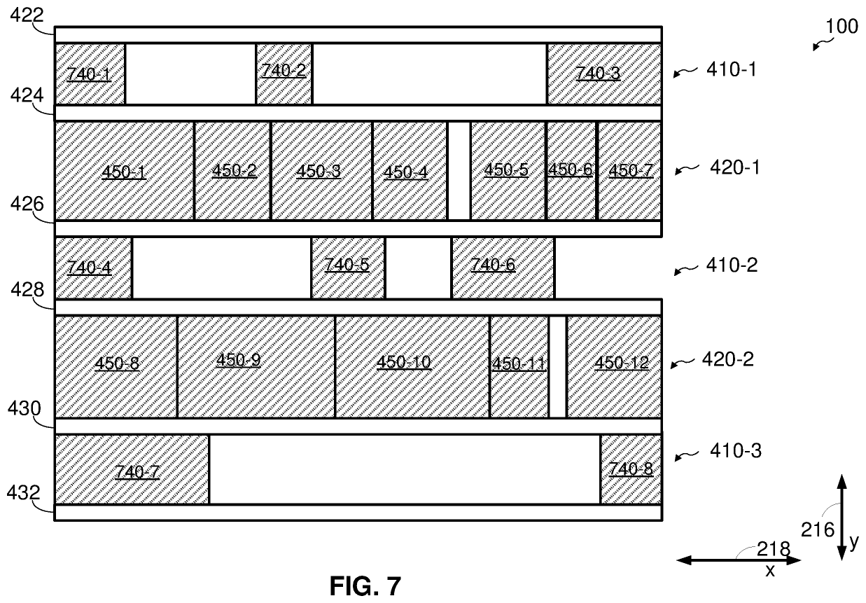

FIG. 7 shows an example of the layout approach illustrated in FIG. 4 for the case where which the tall cells take up a disproportionately larger chip area than the short cells. In this example, the layout includes the tall cells 450-1 to 450-12 discussed above with reference to FIG. 4. However, the layout in this example includes a much smaller number of short cells 740-1 to 740-8 compared with FIG. 4. As shown in FIG. 7, the large imbalance between the tall cells 450-1 to 450-12 and the short cells 740-1 to 740-8 results in large empty spaces in the short rows 410-1, 410-2, and 410-3, and therefore an inefficient use of chip area.

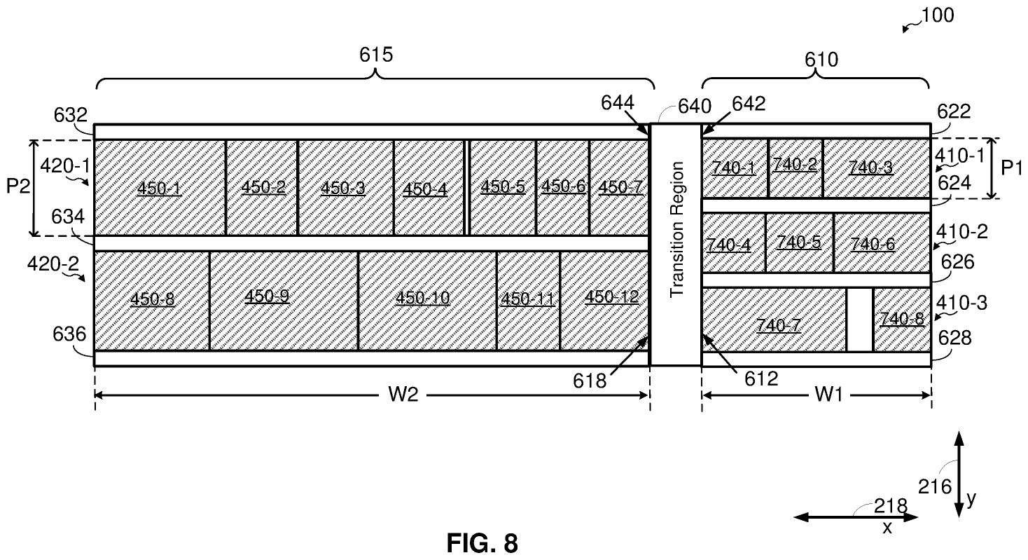

In contrast, FIG. 8 shows an example of the layout approach illustrated in FIG. 6 for the case where which the tall cells take up a disproportionately larger chip area than the short cells. In this example, the second width is greater (i.e., wider) than the first width since the tall cells 450-1 to 450-12 take up a disproportionately larger chip area than the short cells 740-1 to 740-8 in this example (i.e., the area of the tall cells 450-1 to 450-12 is greater than the area of the short cells 740-1 to 740-8). As a result, the width of the short rows 410-1, 410-2, and 410-3 in the first column 610 is smaller than the width of the short rows 410-1, 410-2, and 410-3 in FIG. 7. The smaller width of the short rows 410-1, 410-2, and 410-3 in the first column 610 significantly reduces the amount of empty space in the short rows 410-1, 410-2, and 410-3 compared with the layout in FIG. 7, thereby improving chip area efficiently compared with the layout in FIG. 7.

As discussed above, the transition region 640 provides a transition between the first column 610 and the second column 615. For example, the transition region 640 may provide a transition between the rails 622, 624, 626, and 628 in the first column 610 and the rails 632, 634, and 636 in the second column 615. In this example, the metal pattern forming the rails 622, 624, 626, and 628 in the first column 610 is different from the metal pattern forming the rails 632, 634, and 636 in the second column 620 (e.g., due to differences in rail pitch (i.e., spacing between adjacent rails)). In this example, the metal layer (e.g., metal layer M0) used to form the rails 622, 624, 626, 628, 632, 634, and 636 may be etched away (i.e., cut) in the transition region 640 to provide a transition between the metal pattern forming the rails 622, 624, 626, 628 in the first column 610 and the metal pattern forming the rails 632, 634, and 636 in the second column 615.

The transition region 640 may also provide a transition between OD regions (i.e., active regions) in the first column 610 and OD regions (i.e., active regions) in the second column 615. The transition region 640 may also provide a transition between N wells in the first column 610 and N wells in the second column 615, and/or substrate ties for the first column 610 and the second column 615.

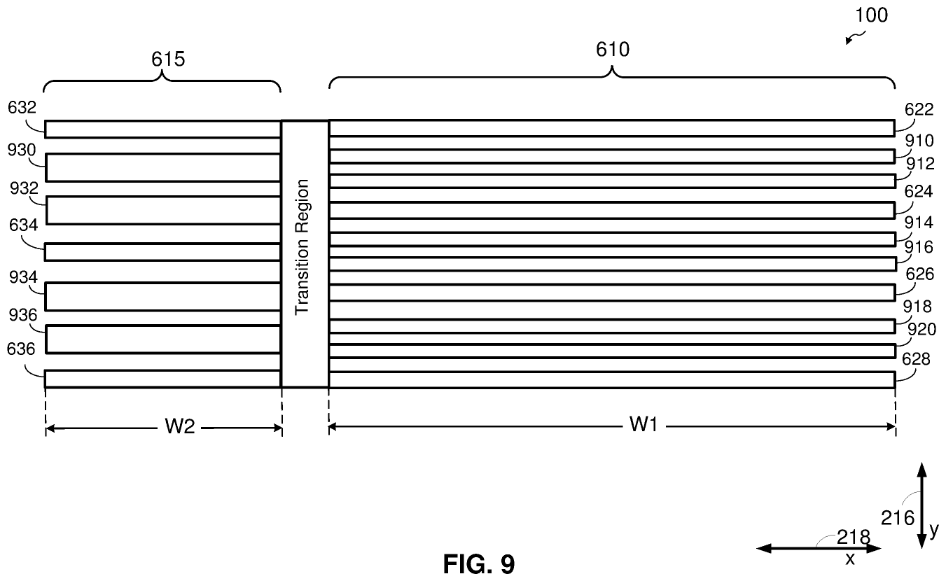

FIG. 9 shows an example in which the transition region 640 provides a transition between OD regions 910, 912, 914, 916, 918, and 920 in the first column 610 and OD regions 930, 932, 934, and 936 in the second column 615. Note that short cells and tall cells are not explicitly shown in FIG. 9 for ease of illustration of the OD regions. The OD regions 930, 932, 934, and 936 in the second column 615 and the OD regions 910, 912, 914, 916, 918, and 920 in the first column 610 may be cut in the transition region 640 to provide the transitions between OD regions 910, 912, 914, 916, 918, and 920 in the first column 610 and OD regions 930, 932, 934, and 936 in the second column 615.

The OD regions 910, 912, 914, 916, 918, and 920 may provide the OD regions for transistors in the short cells (e.g., short cells 440-1 to 440-19 or short cells 740-1 to 740-8) shown in FIG. 6 or FIG. 8. In one example, the OD regions 910, 914, and 918 may be p-type OD regions, and the OD regions 912, 916, and 920 may be n-type OD regions, or vice versa. However, it is to be appreciated that the present disclosure is not limited to this example. Each of the OD regions 910, 912, 914, 916, 918, and 920 extends in the lateral direction 218 (i.e., x direction) and is between a respective pair of the rails 622, 624, 626, and 628. Although not shown in FIG. 9, it is to be appreciated that the OD regions 910, 912, 914, 916, 918, and 920 may be cut between adjacent short cells. The OD regions 910, 912, 914, 916, 918, and 920 may also be referred to as first OD regions.

The OD regions 930, 932, 934, and 936 may provide the OD regions for transistors in the tall cells (e.g., tall cells 550-1 to 550-5 or tall cells 450-1 to 450-12) shown in FIG. 6 or FIG. 8. In one example, the OD regions 930 and 934 may be p-type OD regions, and the OD regions 932 and 936 may be n-type OD regions, or vice versa. However, it is to be appreciated that the present disclosure is not limited to this example. Each of the OD regions 930, 932, 934, and 936 extends in the lateral direction 218 (i.e., y direction) and is between a respective pair of the rails 632, 634, and 636. Although not shown in FIG. 9, it is to be appreciated that the OD regions 930, 932, 934, and 936 may be cut between adjacent tall cells. The OD regions 930, 932, 934, and 936 may also be referred to as second OD regions.

In some implementations, the height of each of the OD regions 930, 932, 934, and 936 in the second column 615 may be taller than the height of each of the OD regions 910, 912, 914, 916, 918, and 920 in the first column 610. For example, the height of each of the OD regions 930, 932, 934, and 936 in the second column 615 may be made larger than the height of each of the OD regions 910, 912, 914, 916, 918, and 920 to accommodate larger transistors in the tall cells in the second column 615 compared with the short cells in the first column. However, it is to be appreciated that the present disclosure is not limited to this example.

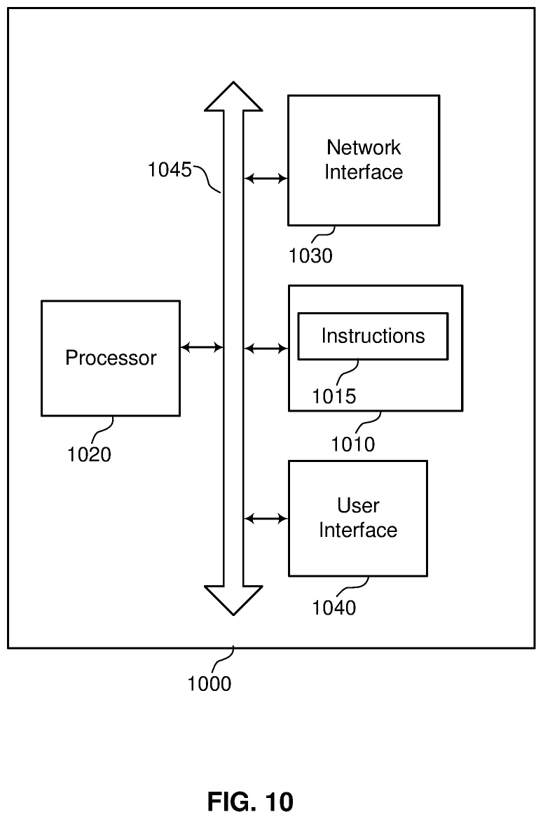

In certain aspects, the exemplary layouts discussed above may be determined using a computer system. In this regard, FIG. 10 illustrates a computer system 1000 that may be used to determine layouts for tall cells and short cells according to certain aspects. The computer system 1000 may include a processor 1020, a memory 1010, a network interface 1030, and a user interface 1040. These components may be in electronic communication via one or more buses 1045.

The memory 1010 may store instructions 1015 that are executable by the processor 1020 to cause the computer system 1000 to perform one or more of the operations described herein. The processor 1020 may include a general-purpose processor, a digital signal processor (DSP), a central processing unit (CPU), a microcontroller, an application specific integrated circuit (ASIC), a field programmable gate array (FPGA), a programmable logic device, a discrete gate or transistor logic component, a discrete hardware component, or any combination thereof. The memory 1010 may include, by way of example, random access memory (RAM), flash memory, read only memory (ROM), programmable read only memory (PROM), erasable programmable read only memory (EPROM), electrically erasable programmable read only memory (EEPROM), registers, magnetic disks, optical disks, hard drives, or any other suitable storage medium, or any combination thereof. The memory 1010 may also store one or more files specifying layouts for tall cells and short cells on the chip.

The network interface 1030 is configured to interface the computer system 1000 with one or more other devices. For example, the network interface 1030 may receive a file indicating tall cells and short cells to be placed on a chip. In this example, the processor 1020 may determine a layout of the tall cells and the short cells on the chip, in which the short cells are arranged in short rows in a first column (e.g., the first column 610), and the tall cells are arranged in rows in a second column (e.g., the second column 615).

The user interface 1040 may be configured to receive data from a user (e.g., via keypad, mouse, etc.) and provide the data to the processor 1020. The user interface 1040 may 1040 may also be configured to output data from the processor 1020 to the user (e.g., via a display, a speaker, etc.).

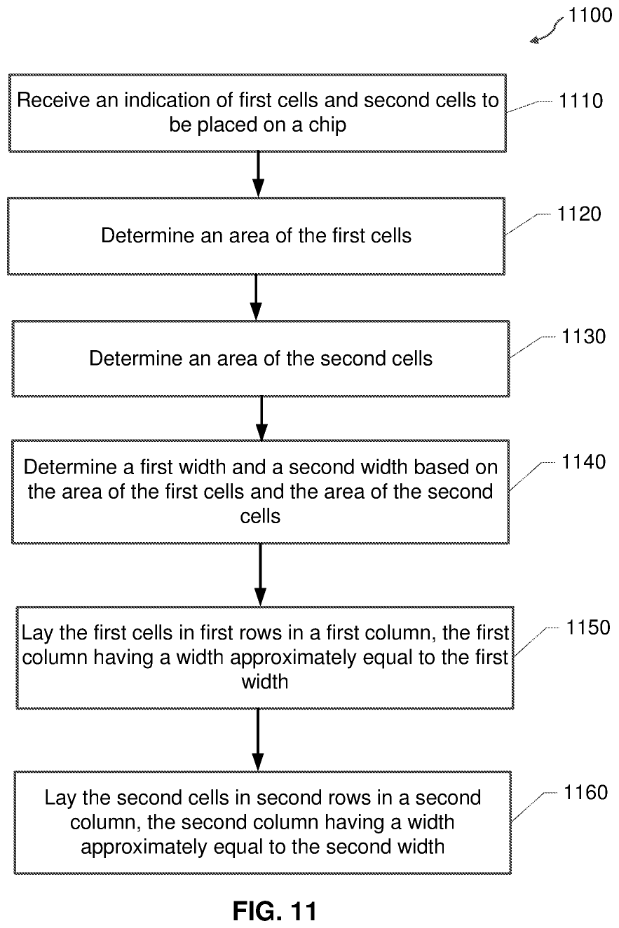

FIG. 11 illustrates a method 1100 for chip layout according to certain aspects of the present disclosure. The method 1100 may be performed by the computer system 1000 according to certain aspects.

At block 1110, an indication of first cells and second cells to be placed on a chip is received, wherein each of the first cells is shorter than each of the second cells in a first direction. For example, the first cells (e.g., short cells) may correspond to the short cells 440-1 to 440-19 or 740-1 to 740-8, the second cells (e.g., tall cells) may correspond to the tall cells 550-1 to 550-5 or 450-1 to 450-12, and the first direction may correspond to lateral direction 216 (i.e., y direction). For example, the network interface 1030 and/or the processor 1020 may receive the indication of the first cells and the second cells (e.g., in a file).

At block 1120, an area of the first cells is determined. For example, the area of the first cells may be determined by summing of the areas of the individual first cells. The processor 1020 may determine the area of the first cells.

At block 1130, an area of the second cells is determined. For example, the area of the second cells may be determined by summing of the areas of the individual second cells. The processor 1020 may determine the area of the second cells.

At block 1140, a first width and a second width are determined based on the area of the first cells and the area of the second cells, wherein the first width and the second width are in a second direction, and the second direction is perpendicular to the first direction.

For example, the second direction may correspond to lateral direction 218 (i.e., x direction). The processor 1020 may determine the first width (e.g., W1) and the second width (W2).

At block 1150, the first cells are laid in first rows in a first column, the first column having a width approximately equal to the first width. For example, the first column may correspond to the first column 610 and the first rows may correspond to the short rows 410-1, 410-2, and 410-3. The processor 1020 may lay the first cells in the first rows in the first column. As used herein, “approximately equal to” is between 95% to 105% of the stated width.

At block 1160, the second cells are laid in second rows in a second column, the second column having a width approximately equal to the second width. For example, the first column may correspond to the second column 620 and the second rows may correspond to the tall rows 420-1 and 420-2. The processor 1020 may lay the second cells in the second rows in the second column.

Implementation examples are described in the following numbered clauses:
1. A chip, comprising:
   a first column comprising first rails extending in a first direction, the first rails having a first pitch;
   a second column comprising second rails extending in the first direction, the second rails having a second pitch different from the first pitch; and
   a transition region between the first column and the second column,
   wherein an edge of the first column abuts a first edge of the transition region, an edge of the second column abuts a second edge of the transition region, the second edge opposing the first edge, and
   wherein the first rails are cut at the first edge and the second rails are cut at the second edge.
2. The chip of clause 1, wherein each of the first rails and each of the second rails is formed from a metal layer M0.
3. The chip of clause 1 or 2, wherein:
   the first column comprises first oxide diffusion (OD) regions extending in the first direction, wherein the first OD regions are cut at the first edge; and
   the second column comprises second OD regions extending in the first direction, wherein the second OD regions are cut at the second edge.
4. The chip of any one of clauses 1 to 3, wherein the first pitch is approximately equal to ⅔ of the second pitch.
5. The chip of any one of clauses 1 to 4, wherein a width of the first column is approximately equal to a first width in the first direction, a width of the second column is approximately equal to a second width in the first direction, and the first width and the second width are different.
6. A chip, comprising:
   a first column comprising first cells arranged in first rows, wherein each of the first rows comprises respective one or more of the first cells, and each of the first rows extends in a first direction; and
   a second column comprising second cells arranged in second rows, wherein each of the second rows comprises respective one or more of the second cells, and each of the second rows extends in the first direction;
   wherein each of the first cells is shorter than each of the second cells in a second direction, and the second direction is perpendicular to the first direction.
7. The chip of clause 6, wherein a height of each of the first cells is approximately equal to a first height in the second direction, a height of each of the second cells is approximately equal to a second height in the second direction, and the first height is equal to ⅔ of the second height.
8. The chip of clause 6 or 7, wherein:
   the first column includes first rails, wherein each of the first rows is between a respective pair of the first rails; and
   the second column includes second rails, wherein each of the second rows is between a respective pair of the second rails.
9. The chip of clause 8, wherein the first rails have a first pitch, and the second rails have a second pitch different from the first pitch.
10. The chip of clause 9, wherein the first pitch is approximately equal to ⅔ of the second pitch.
11. The chip of any one of clauses 8 to 10, wherein each of the first rails and each of the second rails is formed from a metal layer M0.
12. The chip of any one of clauses 6 to 11, wherein a width of the first column is approximately equal to a first width in the first direction, a width of the second column is approximately equal to a second width in the first direction, and the first width and the second width are different.
13. The chip of clause 12, wherein an area of the first cells is greater than an area of the second cells, and the first width is greater than the second width.
14. The chip of clause 12 or 13, wherein an area of the second cells is greater than an area of the first cells, and the second width is greater than the first width.
15. A method for chip layout, comprising:
   receiving an indication of first cells and second cells to be placed on a chip, wherein each of the first cells is shorter than each of the second cells in a first direction;
   determining an area of the first cells;
   determining an area of the second cells;
   determining a first width and a second width based on the area of the first cells and the area of the second cells, wherein the first width and the second width are in a second direction, and the second direction is perpendicular to the first direction;
   laying the first cells in first rows in a first column, the first column having a width approximately equal to the first width; and
   laying the second cells in second rows in a second column, the second column having a width approximately equal to the second width.
16. The method of clause 15, wherein determining the first width and the second width based on the area of the first cells and the area of the second cells comprises determining the first width is greater than the second width if the area of the first cells is greater than the area of the second cells.
17. The method of clause 16, wherein determining the first width and the second width based on the area of the first cells and the area of the second cells comprises determining the second width is greater than the first width if the area of second cells is greater than the area of the first cells.
18. The method of any one of clauses 15 to 17, wherein a height of each of the first cells is approximately equal to a first height in the second direction, a height of each of the second cells is approximately equal to a second height in the second direction, and the first height is equal to ⅔ the second height.

In certain aspects, determining the first width and the second width based on the area of the first cells and the area of the second cells includes determining the first width is greater than the second width if the area of the first cells is greater than the area of the second cells. In certain aspects, determining the first width and the second width based on the area of the first cells and the area of the second cells includes determining the second width is greater than the first width if the area of the second cells is greater than the area of the first cells.

In certain aspects, a height of each of the first cells is approximately equal to a first height in the first direction, a height of each of the second cells is approximately equal to a second height in the second direction, and the first height is equal to ⅔ of the second height.

It is to be appreciated that the layout techniques according to aspects of the present disclosure may be used for FinFETs, planar transistors, gate all around (GAA) transistors, and other types of transistors.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure.

Thus, the disclosure is not intended to be limited to the examples described herein but is to be accorded the widest scope consistent with the principles and novel features disclosed herein.

What is claimed is:

1. A chip, comprising:
a first column comprising first rails extending in a first direction, the first rails having a first pitch;
a second column comprising second rails extending in the first direction, the second rails having a second pitch different from the first pitch; and
a transition region between the first column and the second column,
wherein an edge of the first column abuts a first edge of the transition region, an edge of the second column abuts a second edge of the transition region, the second edge opposing the first edge, and
wherein the first rails are cut at the first edge and the second rails are cut at the second edge.

2. The chip of claim 1, wherein each of the first rails and each of the second rails is formed from a metal layer M0.

3. The chip of claim 1, wherein:
the first column comprises first oxide diffusion (OD) regions extending in the first direction, wherein the first OD regions are cut at the first edge; and
the second column comprises second OD regions extending in the first direction, wherein the second OD regions are cut at the second edge.

4. The chip of claim 1, wherein the first pitch is approximately equal to ⅔ of the second pitch.

5. The chip of claim 1, wherein a width of the first column is approximately equal to a first width in the first direction, a width of the second column is approximately equal to a second width in the first direction, and the first width and the second width are different.

6. A chip, comprising:
a first column comprising first cells arranged in first rows, wherein each of the first rows comprises respective one or more of the first cells, and each of the first rows extends in a first direction; and
a second column comprising second cells arranged in second rows, wherein each of the second rows comprises respective one or more of the second cells, and each of the second rows extends in the first direction;
wherein each of the first cells is shorter than each of the second cells in a second direction, and the second direction is perpendicular to the first direction.

7. The chip of claim 6, wherein a height of each of the first cells is approximately equal to a first height in the second direction, a height of each of the second cells is approximately equal to a second height in the second direction, and the first height is equal to ⅔ of the second height.

8. The chip of claim 6, wherein:
the first column includes first rails, wherein each of the first rows is between a respective pair of the first rails; and
the second column includes second rails, wherein each of the second rows is between a respective pair of the second rails.

9. The chip of claim 8, wherein the first rails have a first pitch, and the second rails have a second pitch different from the first pitch.

10. The chip of claim 9, wherein the first pitch is approximately equal to ⅔ of the second pitch.

11. The chip of claim 8, wherein each of the first rails and each of the second rails is formed from a metal layer M0.

12. The chip of claim 6, wherein a width of the first column is approximately equal to a first width in the first direction, a width of the second column is approximately equal to a second width in the first direction, and the first width and the second width are different.

13. The chip of claim 12, wherein an area of the first cells is greater than an area of the second cells, and the first width is greater than the second width.

14. The chip of claim 12, wherein an area of the second cells is greater than an area of the first cells, and the second width is greater than the first width.

15. A method for chip layout, comprising:
receiving an indication of first cells and second cells to be placed on a chip, wherein each of the first cells is shorter than each of the second cells in a first direction;
determining an area of the first cells;
determining an area of the second cells;
determining a first width and a second width based on the area of the first cells and the area of the second cells, wherein the first width and the second width are in a second direction, and the second direction is perpendicular to the first direction;
laying the first cells in first rows in a first column, the first column having a width approximately equal to the first width; and
laying the second cells in second rows in a second column, the second column having a width approximately equal to the second width.

16. The method of claim 15, wherein determining the first width and the second width based on the area of the first cells and the area of the second cells comprises determining the first width is greater than the second width if the area of the first cells is greater than the area of the second cells.

17. The method of claim 16, wherein determining the first width and the second width based on the area of the first cells and the area of the second cells comprises determining the second width is greater than the first width if the area of second cells is greater than the area of the first cells.

18. The method of claim 15, wherein a height of each of the first cells is approximately equal to a first height in the second direction, a height of each of the second cells is approximately equal to a second height in the second direction, and the first height is equal to ⅔ the second height.
